(19) United States
(12) Patent Application Publication
(10) Pub. No.: US 2024/0231280 A1
(43) Pub. Date: Jul. 11, 2024

(54) METHOD FOR MANUFACTURING A TIMEPIECE MOVEMENT COMPONENT

(71) Applicant: ROLEX SA, Geneva (CH)

(72) Inventors: Pierre Di Luna, Veigy-Foncenex (FR); Stefano Henin, Saint-Prex (CH); Alexandre Oliveira, Amancy (FR); Arnaud Rosenzweig, Collonge-sous-Salève (FR); Pierre Villaret, Villy-le-Pelloux (FR); Benoît Vincent-Falquet, Annecy (FR)

(73) Assignee: ROLEX SA, Geneva (CH)

(21) Appl. No.: 18/563,967

(22) PCT Filed: Jun. 2, 2022
(86) PCT No.: PCT/EP2022/065123

§ 371 Date: Nov. 24, 2023

(30) Foreign Application Priority Data
Jun. 3, 2021 (EP) 21177593.7

(51) Int. Cl. G04D 3/00; B44C 1/22; B44C 1/26; G04B 17/06

(52) U.S. Cl. CPC G04D 3/0069; G04B 17/066; G04D 3/0089; B44C 1/227; B44C 1/228; B44C 1/26

(57) ABSTRACT

The method for manufacturing a timepiece movement component (1) having at least a first portion comprising a surface (11), in particular an upper surface, includes etching (E3) the surface (11) of the timepiece movement component (1) or of a blank (1a) of the timepiece movement component (1) in order to form at least one cavity (7); and depositing a material (E4) in the at least one cavity (7).

The present invention relates to a method for manufacturing a timepiece movement component. It also relates to a timepiece movement component as such obtained by such a manufacturing method.

Various decoration and/or marking methods are implemented on exterior components of a timepiece. Compared to these exterior components, a timepiece movement component is often smaller in size, and includes functional parts of very precise geometry, which must not be altered. Thus, it is very difficult to make markings on such a timepiece movement component, for example for the purpose of identification or decoration. Note that the esthetic aspect is still very important, in particular for a movement component of a timepiece, in addition to its functionality.

Thus, the aim of the present invention is to find a solution for marking and/or decorating a timepiece movement component, which makes it possible to achieve a particularly attractive visual effect without impairing the functionality of the component.

To this end, the invention is based on a method for manufacturing a timepiece movement component comprising at least a first portion comprising a surface, in particular an upper surface, which method comprises at least the following steps:
Etching said surface of the timepiece movement component or a blank of the component to form at least one cavity;
Depositing a material in said at least one cavity.

Said etching may advantageously implement deep reactive ion etching by photolithography through a mask.

The invention also relates to a timepiece movement component which is a hairspring made of micro-machinable material comprising a first portion forming a connection member comprising a surface, in particular an upper surface, and a second portion less rigid than the first portion comprising at least one strip wound in the shape of a spiral forming a spring, and wherein the surface of the first portion comprises at least one cavity in which a layer of material is deposited.

The invention is defined more particularly by the claims.

These aims, features and advantages of the present invention will be explained in detail in the following description of particular embodiments provided on a non-limiting basis with reference to the attached figures, in which:

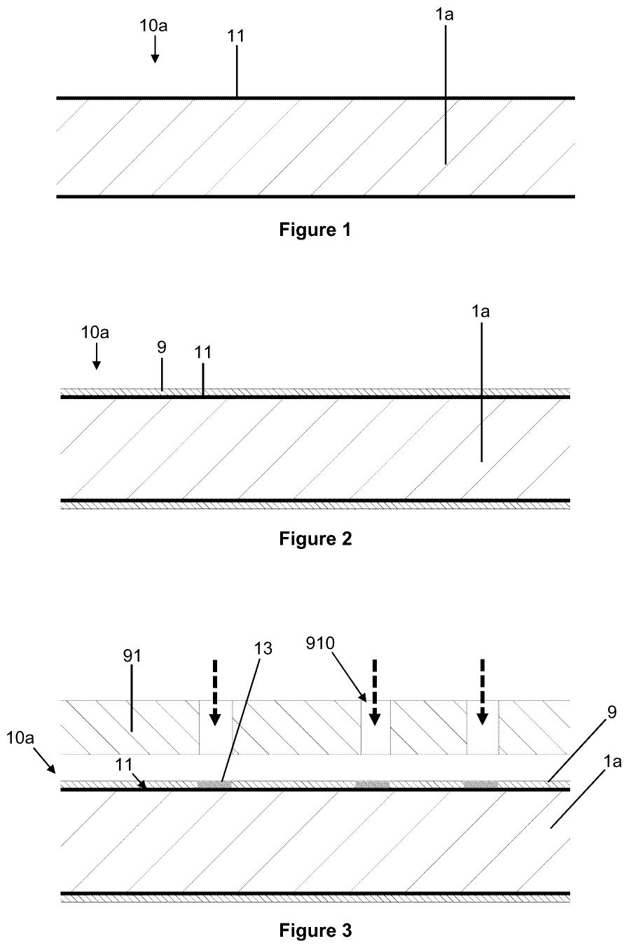

FIGS. 1 to 6 show the successive steps in a method for manufacturing a timepiece movement hairspring according to a first embodiment of the invention.

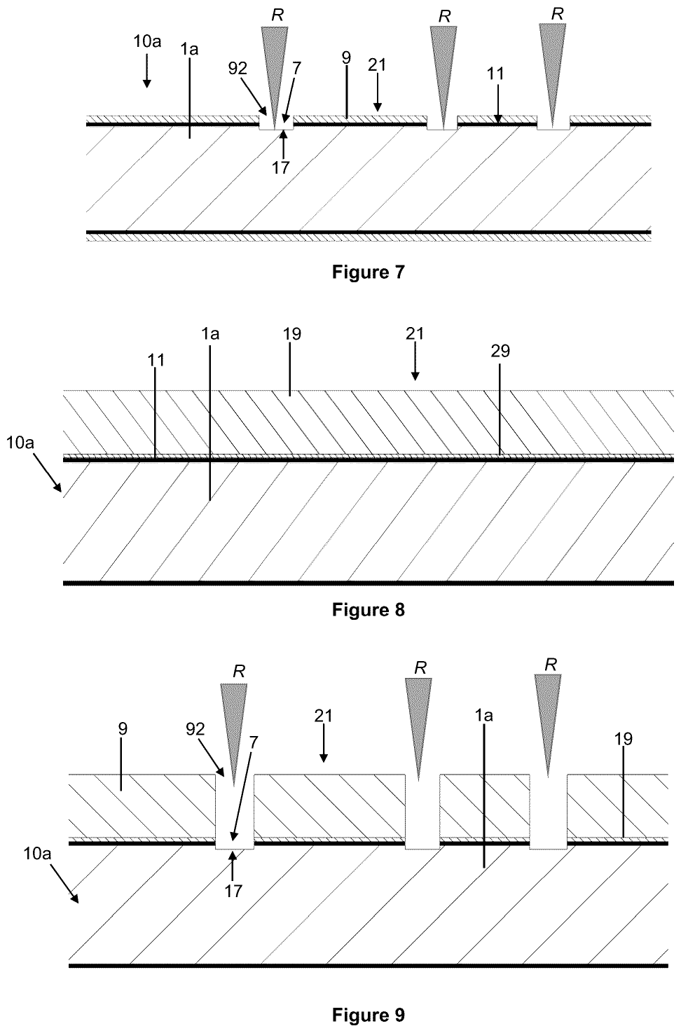

FIG. 7 illustrates a first variant of the first embodiment of the invention.

FIGS. 8 to 10 illustrate a second variant of the first embodiment of the invention.

FIGS. 11 to 13 illustrate a third variant of the first embodiment of the invention.

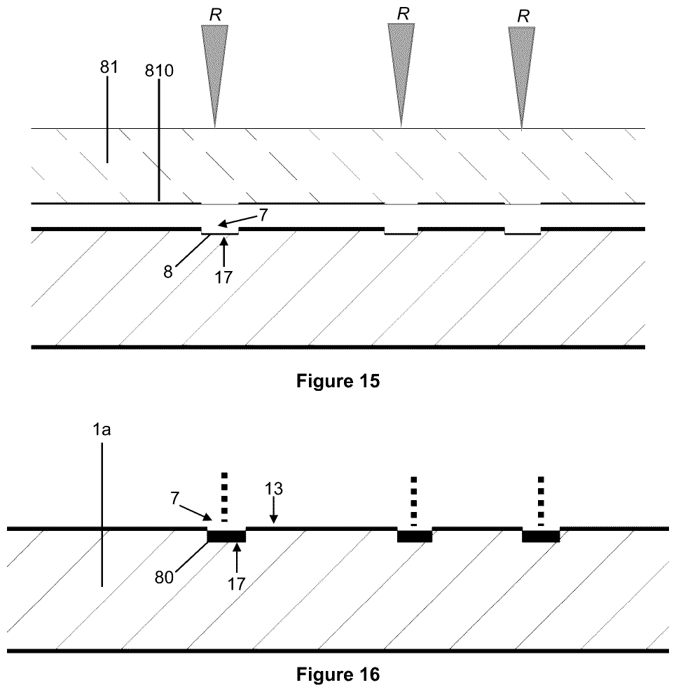

FIGS. 14 and 15 show the successive steps in a method for manufacturing a timepiece movement hairspring according to a second embodiment of the invention.

FIG. 16 illustrates a first variant of the second embodiment of the invention.

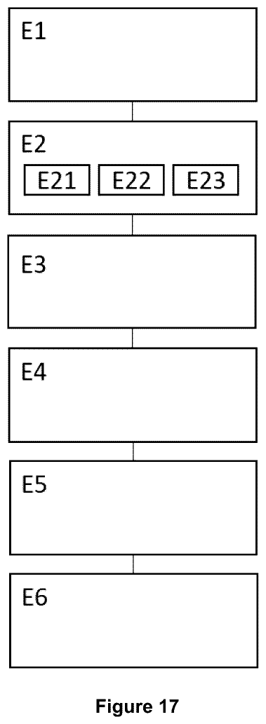

FIG. 17 shows a flowchart schematically depicting the steps and sub-steps in a method for manufacturing a timepiece movement component according to an embodiment of the invention.

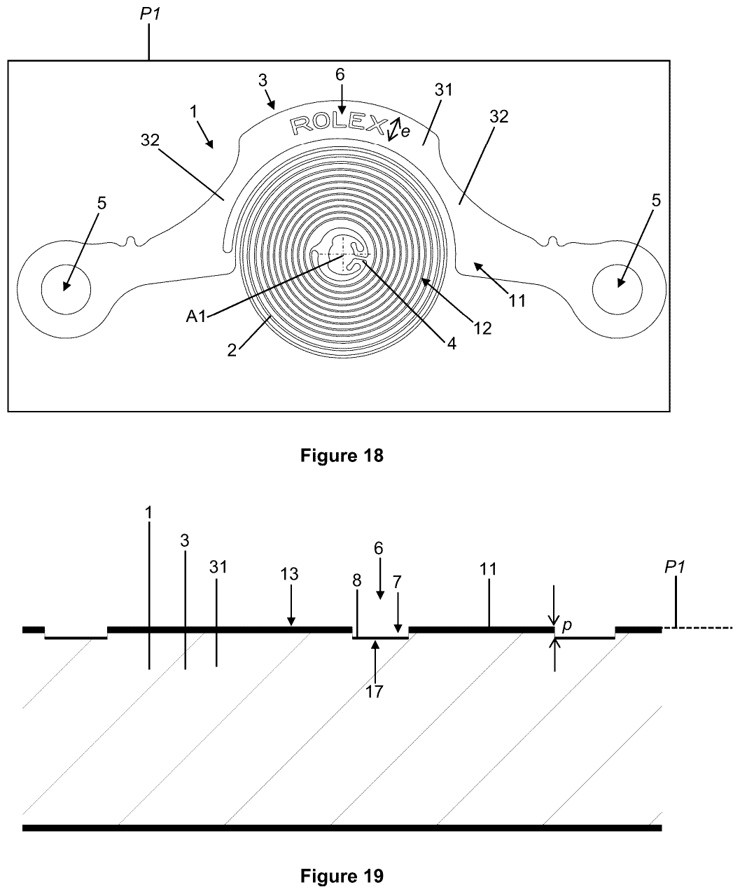

FIG. 18 is a top view of a hairspring produced by a manufacturing method according to an embodiment of the invention.

FIG. 19 shows a view in cross section of the hairspring of FIG. 18.

The invention implements a method for manufacturing a timepiece component which advantageously combines at least a step of etching at shallow depth and a step of coloring said etching obtained, in such a way as to obtain a visible etching which does not affect the functional performance of a movement component.

To facilitate reading of the patent application, the same references will be used in the various embodiments and their variants in order to designate the same features. The manufacturing method according to an embodiment of the invention will be illustrated in the context of the manufacturing of a timepiece movement component, which may for example be a hairspring.

FIGS. 1 to 6 show more particularly views in section of a timepiece movement component 1, or of a blank 1a of the component, during the various steps of its manufacturing according to a first embodiment of a method for manufacturing the timepiece movement component. The manufacturing method of the invention concerns in particular a specific phase of manufacturing, relating to a method for etching a surface. Advantageously, it is a method for etching a visible surface or an upper surface of the timepiece movement component 1, in particular for decorative purposes. Alternatively, it could also be a method for etching a non-visible surface or a lower surface, in particular for identification or marking purposes. This etching method may be implemented in a final phase of manufacturing of the component, or alternatively at various more or less advanced stages of the method for manufacturing the component.

According to this embodiment, the method comprises a first step consisting in providing E1 at least a portion of a blank 1a of the timepiece movement component 1, specifically shown in section in the various figures illustrating the manufacturing method. Note that, according to this advantageous embodiment, several blanks 1a may be connected to the same support or substrate 10a, and may be simultaneously subjected to the method which will be described below, the steps of which are summarized by the flowchart of FIG. 17.

The timepiece component blanks 1a may therefore be manufactured beforehand from a substrate 10a, which is preferably made of micro-machinable material, such as silicon, by micro-manufacturing operations. Note that the term blank will be used in the broad sense, to designate any intermediate element in the method for manufacturing the timepiece component. Thus, the blank may be a substrate supplied and not yet etched, or a substrate already partially etched, for example to define all or part of the contour of the future timepiece component.

The portion of the blank 1a comprises a surface 11 which will be specifically treated by the method according to the invention, with the aim of creating visible patterns or indications on this surface, as will be described in detail below. This surface 11 may comprise a layer of silicon dioxide SiO₂ in one embodiment of using a silicon substrate 10a. The method thus advantageously comprises a prior step of oxidation of the silicon.

FIG. 2 shows a first sub-step E21 of a second step of producing a mask E2, which consists in depositing a layer of photosensitive resin 9 on the surface 11 of the blank 1a. This resin may be deposited using any technique known to those skilled in the art, for example by dip coating or by spray coating or by spin coating. In the example illustrated, it is an acrylic-based positive resin, which is designed to become soluble in a developer under the action of radiation, while the part not exposed to radiation remains insoluble or barely soluble. In the present example, the layer of photosensitive resin is more particularly a layer of resin known by its trade name AZ® 9260, the thickness of which is approximately 6 μm. This sub-step E21 may be followed by an optional sub-step of annealing the resin layer 9 deposited.

FIG. 3 shows a second sub-step E22, in which the resin layer 9 is subjected to UV radiation through the openings 910 in a mask 91. These openings 910 prefigure the visible patterns or indications to be produced on the timepiece movement component, as will be described in detail below. The UV radiation is in this case perpendicular to the plane in which the mask 91 extends, and perpendicular to the surface 11 of the blank 1a, so as to irradiate only the areas 13 of the resin layer 9 located in line with the openings 910 formed in the mask 91.

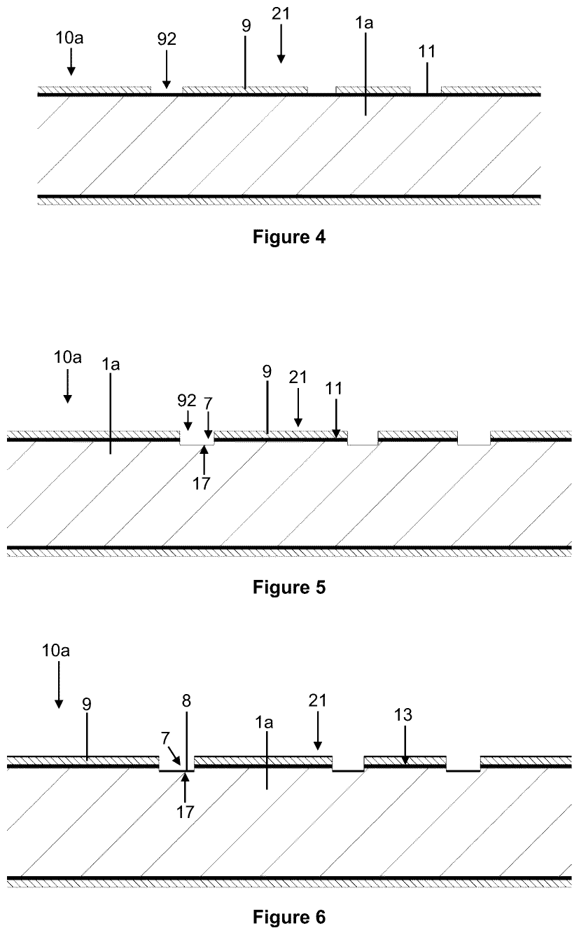

FIG. 4 shows a third sub-step E23, which consists in removing the irradiated resin in the areas 13 in line with the openings 910 in the mask 91, using a solvent. At the end of this sub-step, the resin layer 9 comprises openings 92 on the surface 11, the patterns of which correspond to those of the openings 910. This resin layer 9 with its openings 92 forms a mask 21 intended for the implementation of the etching step which will be described below.

FIG. 5 shows the implementation of a third etching step E3. In this first embodiment, this etching is carried out using a mask 21, made of resin, taking the form of a resin layer 9 deposited on the surface of the component portion, as explained above. According to this embodiment, etching is carried out by deep reactive ion etching (DRIE) technology. This technique makes it possible to form cavities 7 with vertical or substantially vertical sides in line with the openings 92 in the resin layer 9, without affecting the areas of the surface 11 still covered with the resin layer 9. More specifically, the etching step first etches the layer of silicon dioxide present on the surface of the surface 11 of the blank 1a, then etches the silicon, in such a way as to form at least one cavity 7. Each cavity 7 has a section of substantially rectangular shape, delimited by a surface forming a bottom 17, substantially parallel to the surface 11 of the component. The depth of a cavity is measured perpendicular to the surface 11, and corresponds to the respective distance between the planes of the surface 11 and of the bottom 17 of the cavity.

Advantageously, the depth of at least one or of all of the cavities 7 is less than 10 μm, while being preferably equal to or greater than the thickness of the silicon oxide layer.

Note that, advantageously, such an etching step carried out by deep reactive ion etching also makes it possible to obtain a bottom 17 the surface condition of which is notably characterized by a particularly low roughness, specifically with a bottom 17 having a roughness Ra below 50 nm, preferably of the order of 20 nm, or below 20 nm, and/or a roughness Sa below 100 nm, preferably of the order of 80 nm, or below 80 nm, which makes it possible to reveal the luster of the layer of material subsequently deposited on such a bottom 17, as will be explained.

The method then implements a fourth step of deposition of a material E4 in at least one cavity 7, as shown in FIG. 6. Depending on the embodiment, the material is a metal or a metal alloy, and this deposition step forms a layer of metal or metal alloy material 8 on the bottom 17 of the cavities 7.

Preferably, the material is a metal belonging to the group Au, Ag, Cr, CrN, Ni, Pt, TiN, ZrN, Pd or their alloys.

The thickness of this at least one layer of material 8 may be of the order of a few nanometers. It is preferably at least 5 nm, or at least 10 nm, or at least 50 nm, or at least 100 nm. More particularly, it is preferably between 5 nm and 1000 nm, or between 100 nm and 1000 nm.

The step of deposition of a material E4 may include the deposition of just a single layer. Alternatively, this deposition step may comprise the successive deposition of two distinct layers, a first layer deposited directly on the bottom 17 being intended to act as an adhesion layer for a second layer, for example decorative, visible within a cavity 7.

According to one embodiment, the material deposition step E4 is carried out by physical vapor deposition (PVD). More generally, this deposition may be a vapor phase deposition, such as the aforementioned physical deposition (PVD) or chemical deposition (CVD) or atomic deposition (ALD). Note that in such a material deposition step, the mask 21 formed by the resin layer 9 is also used as a mask for this step. This mask 21 makes it possible to guarantee the deposition of material on the bottom 17 of the cavities 7 while protecting the non-etched surface 11 of the portion of the blank 1 in question. More particularly, the material is deposited on the bottom 17 of the cavities, in line with the openings 92 in the mask 21, and also on the resin layer 9 resting on the surface 11.

The method then implements a fifth step of removal E5 of the resin layer 9. This step may be carried out, for example, by dissolution with a chemical or by plasma treatment. At the end of this step, the blank 1a of the timepiece movement component is ready.

Lastly, the method may include a step consisting in detaching E6 the blanks 1a from the substrate 10a. To facilitate the implementation of this step, the component blank may include a partially etched rupture zone, in particular as described in document EP3632839A1.

In variant embodiments, the mask 21 used may be implemented differently than according to the embodiment described in detail above.

FIG. 7 illustrates for this purpose a first variant embodiment, in which the second step of producing a mask E2 is based on the use of a laser. Once the photosensitive resin layer 9 is affixed to the surface 11 of the blank 1a, as shown in FIG. 2, the method implements a step of etching using a laser, in particular a laser with femtosecond pulses, the radiation R of which is predefined according to the chosen pattern. The laser radiation thus etches both the resin layer 9, which corresponds to the step of producing a mask E2 described above, and the upper layer 11 of the blank 1a, which corresponds to the etching step E3 described above. The method then continues with the material deposition step E4, as described above.

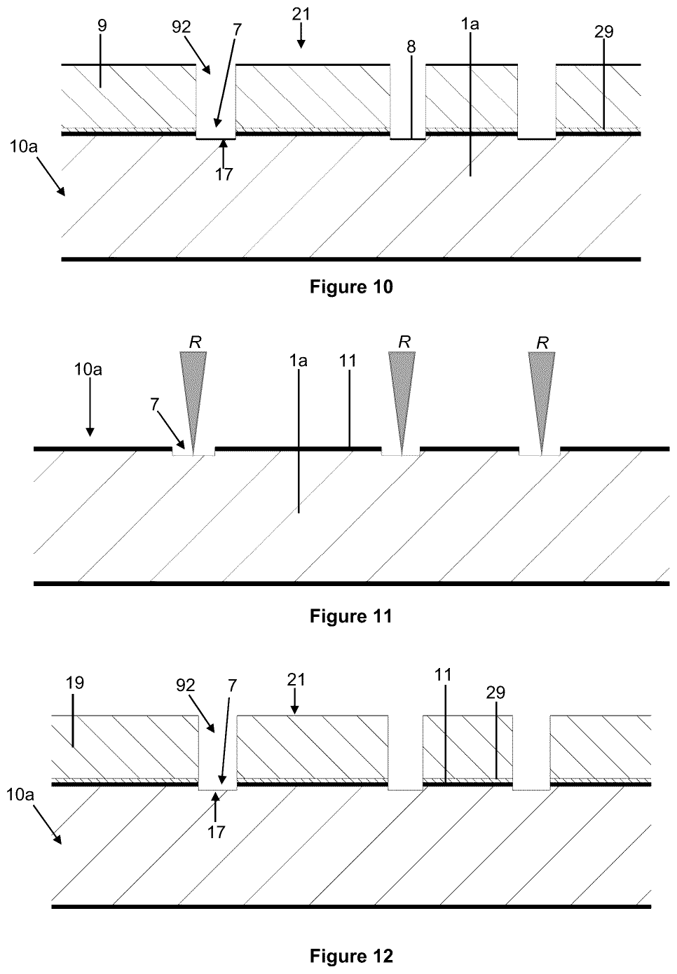

FIGS. 8 to 10 illustrate a second variant embodiment, in which the mask 21 used is no longer made of resin, but is in the form of a plate 19 of rigid material, for example silicon, which is first deposited on the surface 11 of the component blank 1a, as shown in FIG. 8. An intermediate layer 29 of parylene may be deposited between the plate 19 and the blank 1a, to allow the plate 19 to be taken off. The method then uses radiation R from a laser, in particular from a femtosecond pulse laser, which, as in the previous case, forms openings 92 in the mask 21 then forms an etching 7 in the surface 11 of the blank 1a. As in the previous variant, the two steps of producing a mask E2 with openings 92, and of etching E3 are carried out in the same etching step, simultaneously or almost simultaneously. The material deposition step E4 is then carried out in a manner like that described above, as shown in FIG. 10, at the bottom of the cavities 7 through the rigid mask 21.

FIGS. 11 to 13 illustrate a third variant embodiment, in which the mask 21 is placed on the surface 11 of the blank 1a after the etching step E3. To be specific, as shown in FIG. 11, the etching step E3 is carried out using a femtosecond laser, the radiation R of which directly etches the surface 11 of the blank 1a, along a predefined path corresponding to the chosen pattern, without the need for a mask.

After completing etching and producing the etching or etchings 7, the method implements the step of producing a mask E2. This step includes a preliminary step consisting in preparing the mask 21 away from the component blank 1a, by forming an opening 92 in a rigid plate 19, according to the chosen pattern. Then the mask 21 is placed on the surface 11 of the component blank 1a, as shown in FIG. 12. In this step, the mask 21 is positioned on the blank 1a such that its openings 92 are superimposed precisely on the cavities 7 previously made, preferably with a precision of the order of a micron, with the aid of any technique known to those skilled in the art. An intermediate layer 29 of parylene may be deposited between the mask 21 and the surface 11 of the blank 1a, to allow the plate 19 to be taken off.

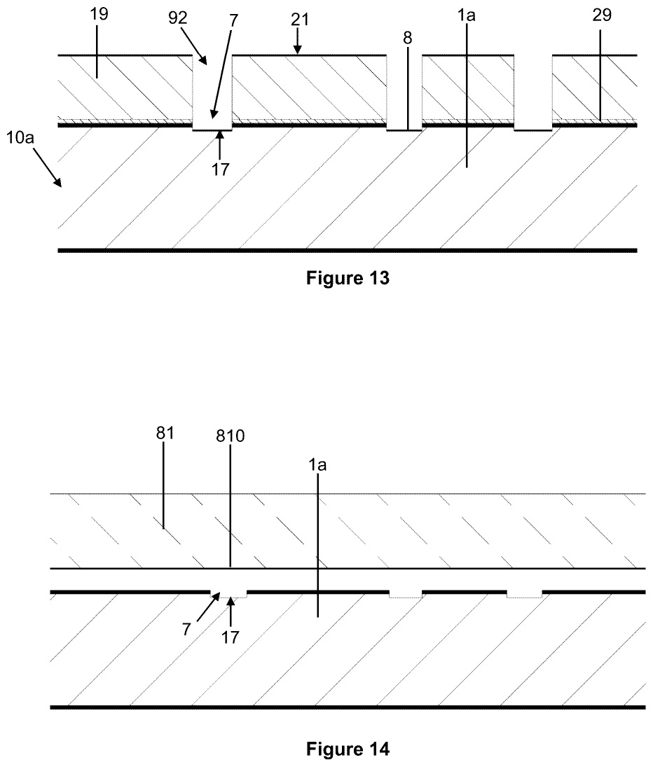

The method then implements the material deposition step E4, which is carried out in a manner like that described above, as shown in FIG. 13, at the bottom of the cavities 7 through the mask 21. In this embodiment, the mask is therefore only used for the material deposition step E4 and no longer for the etching step E3.

In all these previous embodiments which use a mask, the method implements a step of removing E5 the mask after its use.

FIGS. 14 to 16 illustrate a second embodiment, which differs from the first embodiment in that no mask is used, either for the etching step E3 or for the material deposition step E4.

This second embodiment comprises the initial steps identical to the third variant of the first embodiment, up to the production of the etchings 7 in the surface 11 of the blank 1a, as shown in FIG. 11.

Next, the method implements a material deposition step E4 by means of a laser transfer technique, known as LIFT (Laser Induced Forward Transfer). This technique consists in first interposing a transparent metallized plate 81, which includes a metal layer 810 in this embodiment, between laser equipment and the component blank 1a, as shown in FIGS. 14 and 15. Alternatively, a metallized film could be used instead of the metallized plate.

A laser is then directed toward the metallized plate 81, such that the radiation R from the laser beam on the plate 81 strikes the metal layer 810 and generates a mechanical force on said metal layer 810 sufficient to generate a transfer of material from the metallized plate 81 to the component blank 1a. Naturally, the laser radiation is generated with precision, according to the pattern formed by the etching or etchings 7 of the blank 1a, superimposed precisely on this or these etching or etchings 7. Thus, a layer of metal material 8 coming from the metal layer 810 of said metallized plate 81 is transferred to the bottom 17 of the cavity or cavities 7, as shown in FIG. 15. More specifically, this technique makes it possible, using laser pulses, in particular using femtosecond laser pulses, to transfer at least a portion of the metal layer 810 onto the bottom 17 of the cavity or cavities 7, in such a way as to form the layer of material 8. Preferably, the thickness of this layer of material 8 is at least 100 nm.

Lastly, the method implements a final step for detaching the blank or blanks 1a from the substrate 10a.

FIG. 16 illustrates a variant of the second embodiment, in which the material deposition step E4 consists of a step of applying to the bottom 17 of the cavity or cavities 7 a layer of material 8 which is a layer of paint 80, applied by any technique known to those skilled in the art, such as a spraying technique or using a brush. Alternatively, a layer of a lacquer, a varnish or a composite, in particular a luminescent composite, may be applied.

The thickness of said layer of material 8 may correspond to the depth or correspond substantially to the depth of the cavity 7 in which it is deposited. Preferably, the depth is greater than 10 μm, or greater than 15 μm, or greater than 20 μm.

Note that, in all the embodiments and their variants, it is possible as an alternative to carry out the material deposition step E4 after the implementation of the step consisting in detaching E6 the blank 1a from the substrate 10a, in particular in the context of a manual application of the layer 80 as per the embodiment described above.

Furthermore, in all the embodiments, all the steps could be implemented on a component blank alone, not connected to a substrate. They may also be implemented in different steps of the manufacturing of a timepiece movement component, that is to say on a blank of such a timepiece movement component, during manufacturing, or directly on a finished or almost finished timepiece movement component.

According to another advantageous variant embodiment, the invention may be implemented further upstream of the embodiments described above, in particular in the same operation as all or part of the etching of the blank 1a serving to define the contour of the future component, or upstream of the operation of etching the blank 1a serving to define all or part of the contour of the future component. Thus, the method may for example comprise a step of positioning a first mask on the substrate 10a, this first mask serving to perform an etching, in particular a blind etching, of at least one cavity, with a view to deposition of a material in said at least one cavity, according to the principle of the invention. The method may also include another step of positioning a second mask on the substrate 10a, in particular on a second surface of the substrate 10a, this second mask serving to perform an etching of a contour of the component blank 1a. In other words, the etching used to cut the component from the substrate and the etching forming at least one cavity according to the invention may be carried out in the same operation, or partially in the same operation. These two etchings are produced using different masks.

Such a variant of the method is particularly suitable for the manufacture of a hairspring, for which it is particularly advantageous to produce the cavity or cavities of the invention before etching the coils, otherwise it would be difficult in practice to position a resin on coils to etch the cavities of the invention since resin would flow between these coils.

Lastly, the invention appears to achieve the desired aims through the combination of the following two essential steps applied to at least a first portion comprising a surface, in particular an upper surface, of a timepiece movement component blank or of a timepiece movement component:
etching E3 said surface of the blank or of the timepiece movement component to form at least one cavity;
depositing a material E4 in said at least one cavity.

In all the embodiments and their variants, the depth of at least one cavity, and preferably of all the cavities, is advantageously less than 10 μm, or less than 6 μm.

This depth is also optionally greater than 3 μm. Thus, this depth may be between 3 μm and 10 μm, or between 3 μm and 6 μm. Surprisingly, to the naked eye the contrast between at least one cavity 7 and the surface 11 appears all the more marked the shallower the depth of said at least one cavity 7.

Alternatively, the depth of at least one cavity, and preferably of all the cavities, is between 10 μm and 100 μm, or between 15 μm and 80 μm, or between 20 μm and 50 μm.

The depth of at least one cavity, and preferably of all the cavities, may also be greater than or equal to the thickness of a silicon oxide coating present on said surface. Such a silicon oxide coating may comprise a thickness of between 0.5 μm and 5 μm.

At least one cavity, preferably all the cavities, may also have a length of at least 100 μm, or at least 150 μm, or at least 200 μm, or at least 250 μm, in at least one direction. This length may be less than or equal to 800 μm, or less than or equal to 600 μm, or less than or equal to 500 μm, or less than or equal to 400 μm.

The material deposited in the at least one cavity may be a metal or a metal alloy. Alternatively, it may be a paint, a lacquer, a varnish, a composite, in particular a luminescent composite, with optionally an intermediate metal adhesion layer.

In the two embodiments and their variants, the material deposited in the at least one cavity advantageously has a thickness strictly smaller than the depth of the cavity. The deposition thickness may be greater than or equal to 100 nm. It may be between 100 nm and 1000 nm. Alternatively, it may have a thickness equal to or substantially equal to the depth of the cavity.

The invention is especially applicable to any timepiece movement component made of micro-machinable material, that is to say obtained using micro-manufacturing techniques, in particular those involving photolithography or those involving use of a laser. Thus, such a timepiece movement component, in particular its general shape, may for example be obtained, at least partially, by a step of deep reactive ion etching (DRIE). Alternatively, such a timepiece movement component, in particular its general shape, may for example be obtained, at least partially, by UV-Liga (Lithography Galvanik Abformung) technology.

The timepiece movement component according to the invention may comprise, in all or in part, silicon, in any form. It may thus comprise monocrystalline silicon whatever its orientation, polycrystalline silicon, amorphous silicon, amorphous silicon dioxide, doped silicon, whatever the type and level of doping, or porous silicon. It may in particular be manufactured from an SOI (silicon on insulator) substrate.

The timepiece movement component according to the invention may also comprise silicon carbide, glass, ceramic, quartz, ruby or sapphire. Alternatively, it may be made of metal or a metal alloy, in particular a metal alloy that is at least partially amorphous. For example, such a component may comprise Ni or NiP.

Naturally, the invention is not limited to the embodiments described, and it is possible to imagine other implementations, for example by combining the embodiments and/or their variants. In particular, the etching step E3 may combine deep reactive ion etching by photolithography and laser etching, in particular by a femtosecond laser. The invention therefore appears to achieve the desired aims by advantageously combining etching on a surface of a component and partial, or total, filling thereof with a material. This combination makes it possible to form legible marking, in particular visible and attractive marking, even on a small surface, without affecting the functionality of a timepiece movement component. Advantageously, this surface is an upper surface or a visible surface, in particular a visible surface when the component is assembled within a timepiece movement. Alternatively, this surface is a lower surface or a non-visible surface.

The marking may be intended for decorative purposes. Alternatively or additionally, it may be used for identification purposes. The variants of the method according to the invention, which involve a laser, in particular a femtosecond laser, are particularly advantageous in order to individualize the marking on a particular component of the timepiece movement, in particular on a particular hairspring. The marking may, for example, form a serial number or a result of a measurement.

The invention also relates to a timepiece movement component obtained by the manufacturing method described above. The timepiece movement component may be a lever, a wheel, such as a wheel of an escapement device, a pallet assembly, a balance wheel or a hairspring, in particular an oscillator hairspring.

In particular, according to one embodiment, the timepiece movement component may be a hairspring made of micro-machinable material comprising a first portion forming a connection member comprising a surface, in particular an upper or a visible surface, and a second portion less rigid than the first portion comprising at least one strip wound in a spiral forming a spring, the surface of the first portion comprising at least one cavity in which a material is deposited according to the invention. More generally, the timepiece component, or at least the portion comprising the surface considered by the invention, is advantageously based on a micro-machinable material, in particular based on silicon, that is to say comprising by weight at least 50% micro-machinable material.

FIG. 18 shows a hairspring obtained by a manufacturing method according to one of the embodiments described above. It comprises at least one strip 2 the upper surface 12 of which is located in a plane P1, and the outer end of which is made in one piece with a connection member 3 having a rigidity significantly greater than that of the at least one strip 2. The hairspring 1 further comprises a collet 4 of axis A1, which is made in one piece with the inner end of the at least one strip 2.

The connection member 3 comprises a first central portion 31 in the form of a ring portion arranged around the strip 2, the angular extent of which is of the order of 100 degrees with respect to the axis A1. This connection member 3 also comprises two bent portions 32 arranged on either side of the first central portion 31, which each comprise an element 5 for positioning and/or attaching said hairspring, which is in this case in the form of an opening.

The connection member 3 has the particular feature of comprising patterns (or indications) 6 affixed to its upper surface 11, positioned in the plane P1, in particular in its central portion 31. The upper surface 11 is in this case formed in continuity with the upper surface 12 of the at least one strip 2 of the hairspring.

The patterns 6 result from the method described above, and include cavities 7 formed from the upper surface 11, in which a layer of material 8 is deposited.

FIG. 19 shows a view in section of such a hairspring in the central portion 31 of the connection member 3, so as to clearly show the aforementioned patterns 6, formed by cavities 7 of depth p, the bottom 17 of which is covered by a layer of material 8.

Surprisingly, to the naked eye the contrast between the patterns 6 and the upper surface 11 of the connection member 3 appears all the more marked when a cavity 7 has a depth p, measured perpendicular to the plane P1 between respectively the upper surface 11 and the bottom 17 of the cavities 7, which is as shallow as possible. Alternatively, this depth may be considered between respectively the upper surface 11 and the upper surface of the layer of material 8 deposited on the bottom 17 of the cavities 7, the thickness of which is very small.

In addition, the extent e of the patterns, measured radially relative to the axis A1, may for its part be greater than 100 μm, or greater than 150 μm, or greater than 200 μm, or greater than 250 μm. Such patterns or indications 6 may thus be visible or legible once the hairspring 1 is mounted within an assembled balance wheel, itself assembled within a timepiece movement.

This hairspring may be a hairspring for a free sprung balance. It may be in one piece. It may be made of silicon. The surface considered by the invention may be covered with a coating of silicon oxide. Alternatively, it may be made from an SOI (silicon on insulator) substrate.

The invention also relates to a timepiece movement comprising such a timepiece movement component. It also relates to a timepiece which includes at least one such timepiece movement or one such timepiece movement component.

1. A method for manufacturing a timepiece movement component comprising at least a first portion comprising a surface, the method comprising:
etching the surface of the timepiece movement component or of a blank of the timepiece movement component to form at least one cavity, the etching implementing deep reactive ion etching by photolithography through a mask; and
depositing a material in the at least one cavity.

2. The method as claimed in claim 1, wherein a depth of the at least one cavity is less than 10 μm.

3. The method as claimed in claim 1, wherein a depth of the at least one cavity is in a range of from 10 μm to 100 μm.

4. The method as claimed claim 1, wherein the at least one cavity extends over the surface over a length of at least 100 μm in at least one direction.

5. The method as claimed in claim 1, wherein the first portion comprising the surface is in a micro-machinable material.

6. The method as claimed in claim 1, wherein
the etching of the surface of the first portion of the timepiece movement component is carried out in a same operation as etching a contour of the timepiece movement component, and/or
the etching the surface of the first portion of the timepiece movement component is carried out before etching the contour of the timepiece movement component, and/or
the method comprises:
positioning a first mask on a substrate so as to carry out the etching of the at least one cavity from the first mask, and
positioning a second mask on the substrate so as to etch a contour of the blank of a timepiece movement component from the second mask.

7. The method as claimed in claim 1, wherein the etching of the surface of the first portion of the timepiece movement component or of a blank of the timepiece movement component further comprises laser etching.

8. The method as claimed in claim 1, wherein the depositing of the material in the at least one cavity comprises depositing a metal, a metal alloy, a paint, a lacquer, a varnish, or a composite.

9. The method as claimed in claim 8, wherein the depositing of the material in the at least one cavity comprises depositing a metal or a metal alloy by vapor phase deposition.

10. The method as claimed in claim 1, wherein
the depositing of the material in the at least one cavity comprises depositing the material on a bottom of the cavity to a thickness strictly smaller than a depth of the cavity, a thickness of the material deposited being greater than or equal to 5 nm, or
the depositing of the material in the at least one cavity comprises depositing the material on the bottom of the cavity to a thickness equal or substantially equal to the depth of the cavity.

11. The method as claimed in claim 1, comprising:
before the etching of the surface and the depositing of the material, providing a substrate based on a micro-machinable material comprising one or more blanks of the timepiece movement component to be manufactured; and
before or after the depositing of the material in the at least one cavity of the surface of the at least one first portion of the at least one blank of the timepiece movement component, detaching the at least one blank of the timepiece movement component from the substrate.

12. The method as claimed in claim 1, wherein the timepiece component is a lever, a wheel, a pallet assembly, a balance wheel, or a spring.

13. A timepiece movement component manufactured by the manufacturing method as claimed in claim 1, which is a hairspring made of micro-machinable material comprising a first portion forming a connection member comprising a surface, and a second portion less rigid than the first portion comprising at least one strip wound in a spiral forming a spring, and wherein the surface of the first portion comprises the at least one cavity in which a layer of the material is deposited.

14. The timepiece movement component as claimed in claim 13, which is a one-piece hairspring for a balance wheel/hairspring, made of silicon covered with a coating of silicon oxide.

15. The timepiece movement component as claimed in claim 13, wherein
a depth of the at least one cavity is less than 10 μm, and/or
the depth of the at least one cavity is greater than or equal to a thickness of a silicon oxide coating on the upper surface, and/or
a length of the at least one cavity is at least 100 μm in at least one direction.

16. The timepiece movement component as claimed in claim 13, wherein
the material deposited in the at least one cavity is a metal, a metal alloy, a paint, a lacquer, a varnish, or a composite, and/or
the material deposited in the at least one cavity has a thickness strictly smaller than a depth of the cavity, a thickness of the material deposited being greater than or equal to 5 nm or substantially equal to the depth of the cavity.

17. The method as claimed in claim 5, wherein the micro-machinable material comprises a base of silicon and a silicon oxide coating having a thickness in a range of from 0.5 μm to 5 μm.

18. The method as claimed in claim 7, wherein the laser etching is performed using a femtosecond laser.

19. The method as claimed in claim 8, wherein the depositing of the material in the at least one cavity comprises depositing a composite, the composite being.

20. The method as claimed in claim 19, comprising, prior to the depositing of the material in the at least one cavity, depositing an adhesion layer.
